(19) United States
(12) Patent Application Publication
(10) Pub. No.: US 2015/0241369 A1
(43) Pub. Date: Aug. 27, 2015

(54) CHARGED PARTICLE BEAM APPARATUS, IMAGE ACQUIRING METHOD AND NON-TRANSITORY COMPUTER-READABLE RECORDING MEDIUM

(71) Applicant: Kabushiki Kaisha Toshiba, Minato-ku (JP)

(72) Inventor: Osamu NAGANO, Kuwana (JP)

(73) Assignee: Kabushiki Kaisha Toshiba, Minato-ku (JP)

(21) Appl. No.: 14/510,210

(22) Filed: Oct. 9, 2014

Related U.S. Application Data
(60) Provisional application No. 61/944,979, filed on Feb. 26, 2014.

(51) Int. Cl. G01N 23/225; H01J 37/244; H01J 37/28

(52) U.S. Cl. CPC G01N 23/225; H01J 37/28; H01J 37/244

(57) ABSTRACT

In accordance with an embodiment, a charged particle beam apparatus includes a charged particle source to generate a charged particle beam and irradiates a substrate with it, a detector to detect secondary charged particles from the substrate and output a signal, a deflector, a signal processing unit, a scanning procedure determination unit and a deflector control unit. The substrate has an inspection region where patterns are arranged and a non-inspection region. The signal processing unit processes the signal from the detector by scanning with a first beam for position detection to output positional information. The scanning procedure determination unit determines a procedure of scanning with a second beam for inspection on the basis of the positional information. The deflector control unit controls the deflector in such a manner that the inspection region is scanned with the second beam in a second direction in accordance with the determined scanning procedure.

### CROSS REFERENCE TO RELATED APPLICATIONS

This application is based upon and claims the benefit of U.S. provisional Application No. 61/944,979, filed on Feb. 26, 2014, the entire contents of which are incorporated herein by reference.

### FIELD

Embodiments described herein relate generally to a charged particle beam apparatus, a charged particle beam scanning method and a non-transitory computer-readable recording medium.

### BACKGROUND

As a defect inspection method of a circuit pattern formed on a wafer, there has been used a defect inspection method of an SEM system to which a scanning electron microscope (SEM) technology is applied. The SEM system has a higher resolving power (resolution) as compared with an inspection method of an optical system to which an optical microscope technology is applied. Hence the SEM system has the advantage that a detection sensitivity of a defect is very high. On the other hand, the SEM system has, on the principle thereof, the problem that beam scanning requires time and thus an inspection time is very long.

### BRIEF DESCRIPTION OF THE DRAWINGS

In the accompanying drawings:

FIG. 1 is one example of a block diagram schematically showing a constitution of a charged particle beam apparatus according to one embodiment;

FIG. 2 is a view showing one example of an inspection object pattern;

FIG. 3 and FIG. 4 are diagrams explaining one example of a pattern inspection in which the charged particle beam apparatus shown in FIG. 1 is used;

FIG. 5 to FIG. 10 are diagrams explaining another example of the pattern inspection in which the charged particle beam apparatus shown in FIG. 1 is used;

FIG. 11 is a flowchart showing one example of a specific procedure of a charged particle beam scanning method according to one embodiment; and

FIG. 12 is a diagram showing another example of the inspection object pattern.

### DETAILED DESCRIPTION

In accordance with an embodiment, a charged particle beam apparatus includes a charged particle source, a detection unit, and a deflector, a signal processing unit, a scanning procedure determination unit, a deflector control unit, and a control unit. The charged particle source generates a charged particle beam, and irradiates a substrate with the charged particle beam. The substrate has an inspection region and a non-inspection region. Inspection object patterns are arranged in the inspection region. The detection unit detects secondary charged particles from the substrate irradiated with the charged particles to output a signal. The deflector scans the substrate with the charged particle beam. The signal processing unit processes the signal outputted from the detection unit by scanning with a first beam for position detection to output positional information of the inspection region in a first direction. The scanning procedure determination unit determines a procedure of scanning with a second beam for inspection on the basis of the positional information. The deflector control unit controls the deflector in such a manner that the inspection region is scanned with the second beam in a second direction intersecting the first direction in accordance with the determined scanning procedure. The control unit controls the charged particle source and the deflector control unit in such a manner that the scanning with the first and second beams is performed for every inspection unit constituted of a pair or a plurality of pairs of the inspection regions and the non-inspection regions.

Embodiments will now be explained with reference to the accompanying drawings. Like components are provided with like reference signs throughout the drawings and repeated descriptions thereof are appropriately omitted.

In the following description, as one example of the charged particle beams, electron beams will be described, but the present invention is not limited to this example, and is applicable to, for example, ion beams.

(1) Charged Particle Beam Apparatus

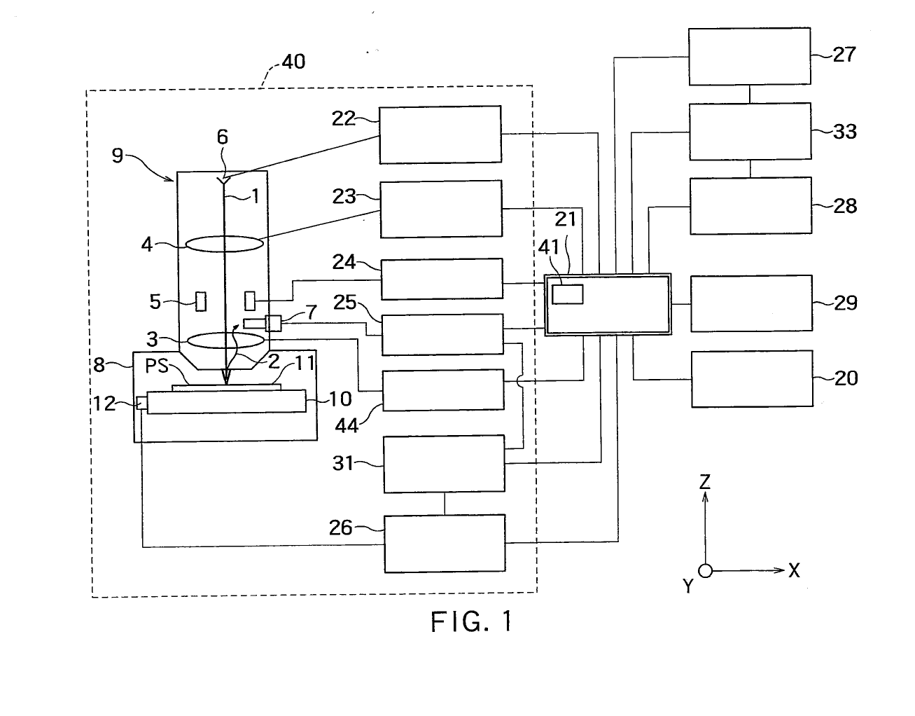

FIG. 1 is a block diagram schematically showing a constitution of a charged particle beam apparatus according to one embodiment. An electron beam inspection apparatus shown in FIG. 1 includes a scanning electron microscope 40, a control computer 21, an inspection unit 33, a design database 27, a storage device 28, a display device 29, and an input device 20. The control computer 21 is also connected to the design database 27, the storage device 28, the display device 29 and the input device 20.

The scanning electron microscope 40 includes an electron optical column 9, a sample chamber 8, an electron gun control unit 22, lens control units 23, 44, a deflector control unit 24, a signal processing unit 25, an image generation unit 31, and a stage control unit 26. In the electron optical column 9, an electron gun 6, a condenser lens 4, a deflector 5, an objective lens 3 and a detector 7 are disposed. Furthermore, in the sample chamber 8, the lens 4, the deflector 5, the objective lens 3 and the detector 7 are disposed. Furthermore, in the sample chamber 8, there are disposed a stage 10 supporting a substrate 11 as a sample in which inspection object patterns are formed, and an actuator 12.

The control computer 21 is also connected to the electron gun control unit 22, the lens control units 23, 44, the deflector control unit 24, the signal processing unit 25, the image generation unit 31, and the stage control unit 26.

The electron gun control unit 22 is connected to the electron gun 6 in the electron optical column 9, the lens control unit 23 is connected to the condenser lens 4, the lens control unit 44 is connected to the objective lens 3, the deflector control unit 24 is connected to the deflector 5, and the signal processing unit 25 is connected to the detector 7. The image generation unit 31 is connected to the signal processing unit 25. The stage control unit 26 is connected to the actuator 12 in the sample chamber 8.

The electron gun control unit 22 generates a control signal in accordance with an instruction of the control computer 21, and upon receiving this control signal, the electron gun 6 generates and emits an electron beam 1. The emitted electron beam 1 is focused and a focal position is regulated by the condenser lens 4 and the objective lens 3 to irradiate the substrate 11.

The lens control unit 23 generates a control signal in accordance with an instruction of the control computer 21, and upon receiving this control signal, the condenser lens 4 focuses the electron beam 1 thereon.

The lens control unit 44 generates a control signal in accordance with an instruction of the control computer 21, and upon receiving this control signal, the objective lens 3 regulates a focal position of an electron beam EB, and allows the just focused electron beam EB to enter into the substrate 11.

The deflector control unit 24 generates a control signal in accordance with an instruction of the control computer 21, and upon receiving the control signal sent from the deflector control unit 24, the deflector 5 forms a deflection electric field or a deflection magnetic field, and suitably deflects the electron beam 1 in an X-direction and a Y-direction to scan the surface of the substrate 11.

A secondary electron, a reflected electron and a backscattered electron are generated from a principal surface PS of the substrate 11 irradiated with the electron beam 1, and detected by the detector 7, so that a detection signal is sent to the signal processing unit 25.

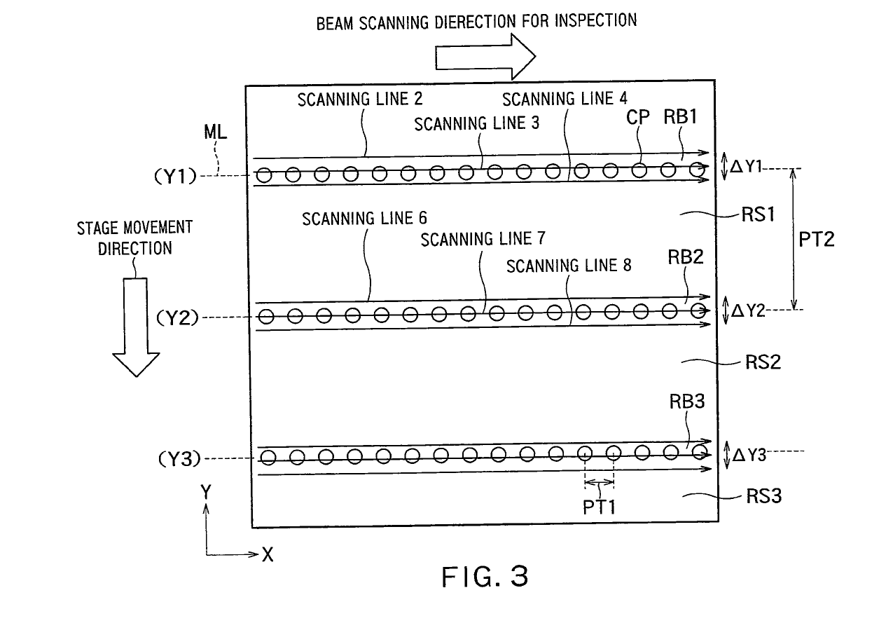

When the electron beam 1 is applied for position detection, the signal processing unit 25 analyzes the detection signal from the detector 7 to specify a position of each inspection region RB (see RB1 to RB3 of FIG. 3) in the Y-direction, and sends the positional information to a scanning procedure determination unit 41. The scanning procedure determination unit 41 is disposed in the control computer 21, and processes the detection signal of the inspection region RB which is sent from the signal processing unit 25, to determine a scanning procedure with the electron beam 1 for an inspection on the basis of the positional information of the inspection regions RB (see RB1 to RB3 of FIG. 3) in the Y-direction.

The beam scanning for the inspection is performed to each inspection region RB (see RB1 to RB3 of FIG. 3) in the X-direction. Upon receiving the control signal from the control computer 21, the deflector control unit 24 generates a deflection control signal and sends the signal to the deflector 5 so as to deflect the beam to the inspection region RB (see RB1 to RB3 of FIG. 3) in the X-direction.

The control computer 21 generates various control signals in addition to the control signal to the deflector control unit 24, and sends the control signals to the electron gun control unit 22, the lens control unit 23 and the stage control unit 26. In consequence, the beam scanning is performed in accordance with the above scanning procedure.

When the inspection region RB is scanned with the electron beam 1, the secondary electron, the reflected electron and the backscattered electron (hereinafter simply referred to as “the secondary electron and the like”) are generated from the inspection region RB, and detected by the detector 7, so that the detection signal is sent to the signal processing unit 25. In the present embodiment, the secondary electron and the like correspond to, for example, secondary charged particles.

When the electron beam 1 is applied for the inspection, the detection signal from the detector 7 is processed by the signal processing unit 25 and sent to the image generation unit 31. The image generation unit 31 generates an image (an SEM (Scanning Electron Microscope) image) of each pattern in each inspection region RB from the signal sent from the signal processing unit 25. The SEM image is displayed by the display device 29 via the control computer 21, and stored in the storage device 28.

The inspection unit 33 takes the SEM image from the storage device 28 to detect presence a defect of each inspection object pattern, a type of defect or a degree of the defect by a die to die inspection, or by a die to database inspection with reference to the design database 27. The detection result is sent to the control computer 21, displayed by the display device 29, and stored in the storage device 28.

The stage 10 is movable in the X-direction, the Y-direction and a Z-direction, and the actuator 12 moves the stage 10 in accordance with the control signal generated by the stage control unit 26 following the instruction from the control computer 21.

The design database 27 includes CAD data of each inspection object pattern. The storage device 28 stores a recipe file in which an after-mentioned pattern inspection procedure is described, and this recipe file is read by the control computer 21 to execute a pattern inspection.

The input device 20 is an interface to input, into the control computer 21, information such as a coordinate position of an inspection area, a type of inspection pattern, inspection conditions, and various threshold values for defect detection.

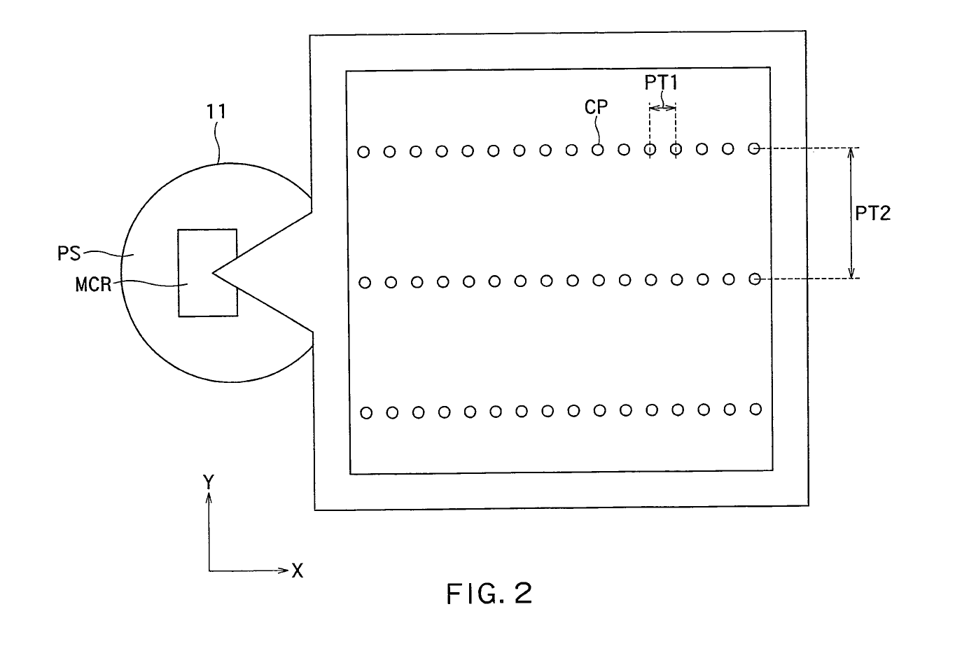

The pattern inspection in which the electron beam apparatus shown in FIG. 1 is used will be described with reference to FIG. 2 to FIG. 10.

FIG. 2 is a view showing one example of each inspection object pattern. In the present embodiment, there will be described bit line contacts (hereinafter referred to as “contact hole patterns”) of a flash memory which are formed in a memory cell region MCR of the principal surface PS of the substrate 11.

In FIG. 2, contact hole patterns CPs are periodically arranged at a first pitch PT1 in the X-direction so as to form a row pattern, and the row patterns are repeatedly arranged at a second pitch PT2 in the Y-direction. Here, the second pitch PT2 is larger than the first pitch PT1. In the following description, the X-direction corresponds to, for example, the second direction, and the Y-direction corresponds to, for example, the first direction.

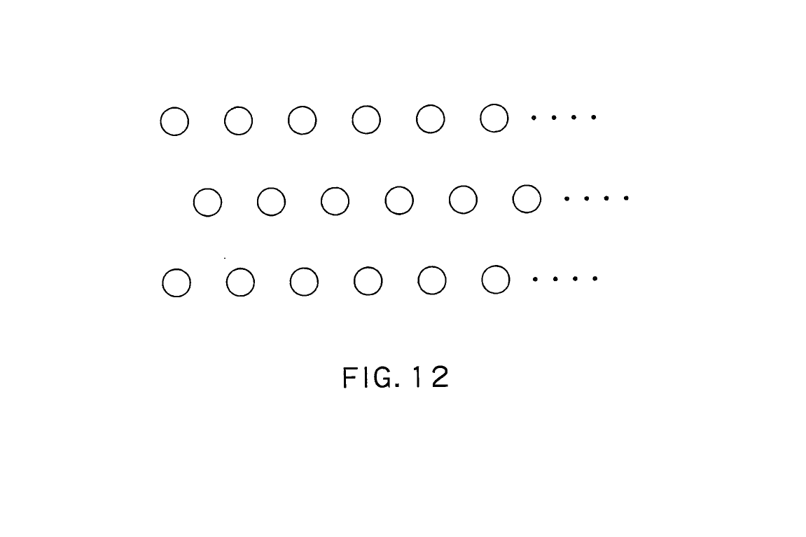

It is to be noted that the inspection object patterns are never limited to patterns regularly arranged in a matrix manner as shown in FIG. 2, but may be, for example, patterns in which a position of each pattern in the X-direction shifts every row as shown in FIG. 12. Furthermore, the inspection object patterns are not limited to lattice patterns, but the pattern inspection of the present embodiment is applicable to any pattern, as long as the pattern is constituted of an individual pattern in which periodic patterns are arranged in parallel via a predetermined space in the first direction and arranged via a predetermined space in the second direction intersecting the first direction.

First, the control computer 21 reads the recipe file from the storage device 28, and sets, in a recipe, the inspection region RB in which a desirable inspection object pattern is present and a non-inspection region RS other than the inspection region, with reference to a pattern layout in the design database 27. As described above, the inspection region RB in which the desirable inspection object pattern is present is only selectively scanned with the beams, so that a beam scanning area is minimized, and the inspection can be speeded up.

The contact hole patterns CPs shown in FIG. 2 will be described. As shown in FIG. 3, a line connecting centers of the contact hole patterns CPs in the X-direction is a center line ML, and on the basis of the pattern layout, regions having a width of ΔY in the Y-direction are set to inspection regions RB1, RB2, RB3, . . . , and regions sandwiched between these inspection regions are set to non-inspection regions RS1, RS2, RS3, . . . The non-inspection regions RS1, RS2, RS3, . . . are regions skipped without being irradiated with the electron beam for the inspection.

The width ΔY of the inspection region RB is set in accordance with the number of scanning lines capable of securely passing edges of the contact hole patterns CPs in the beam scanning for the inspection. In the example shown in FIG. 3, a width corresponding to three scanning lines is set.

Next, the beam scanning to detect the position of the inspection region RB is performed. First, upon receiving the control signal from the stage control unit 26, the actuator 12 moves the stage 10. An example of a stage moving system is a system in which movement and stop are repeated, but in the present embodiment, to shorten an inspection time, a continuous movement system to always move the stage at a constant speed is employed. As a direction of the stage movement, there is selected a direction in which the pattern pitch of the contact hole patterns CPs is larger, and in the example shown in FIG. 3, the direction is set to the Y-direction which is a direction of the second pitch PT2.

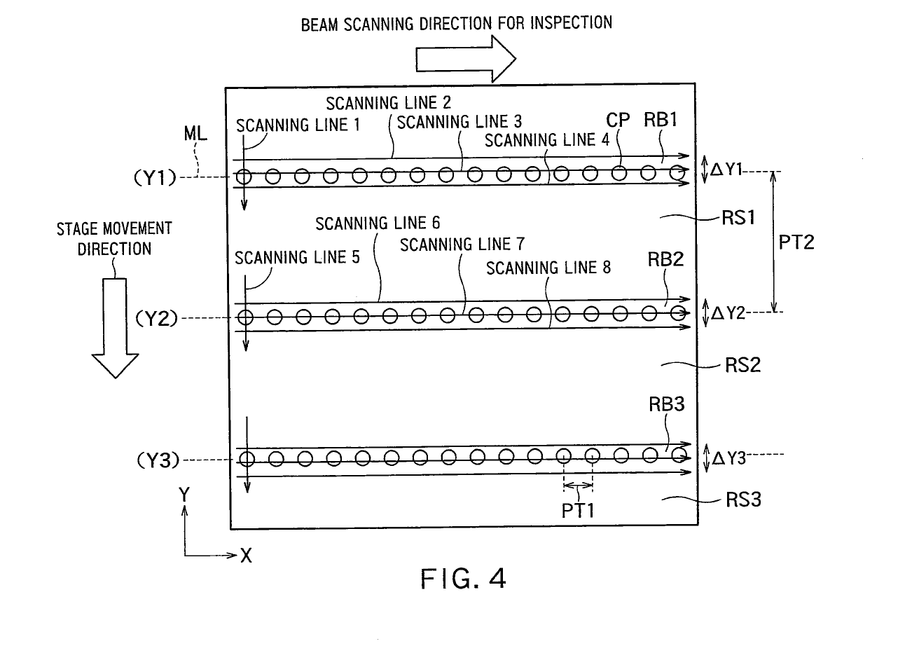

When the stage 10 is moved to a predetermined position, the electron gun 6 generates the electron beam 1 upon receiving the control signal from the electron gun control unit 22, and the deflector deflects the electron beam 1 in the Y-direction upon receiving the control signal from the deflector control unit 24. In an example shown in FIG. 4, the beam scanning to detect the position of the inspection region RB (a scanning line 1) is performed prior to the beam scanning for the inspection to acquire inspection images (scanning lines 2 to 4).

By the beam scanning for the position detection (the scanning line 1), the secondary electron, the reflected electron and the backscattered electron are generated from the surface of the substrate 11, these secondary charged particles are detected by the detector 7, and the detection signal is sent to the signal processing unit 25.

When the contact hole patterns CPs are scanned in the process of the beam scanning with the scanning line 1 in the Y-direction, an amount of the secondary electron and the like obtainable from the substrate 11 changes. The signal processing unit 25 analyzes the detection signal from the detector 7 to specify the position of the inspection region RB in the Y-direction, and sends the position as the positional information to the scanning procedure determination unit 41 in the control computer 21.

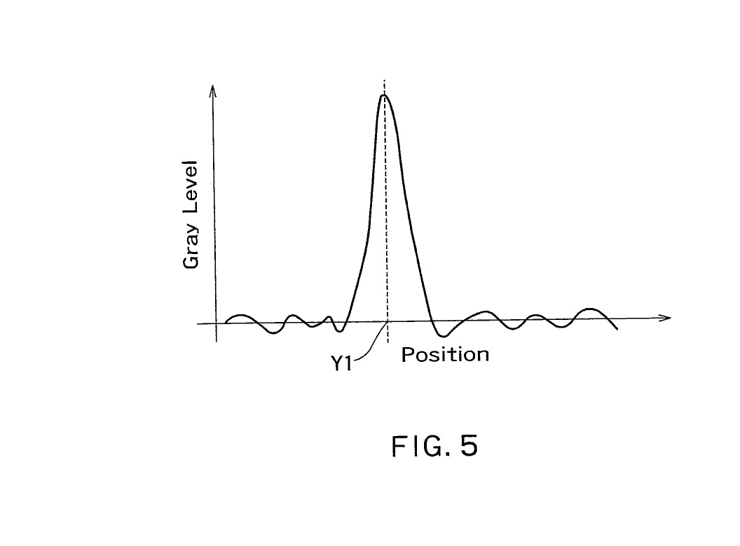

More specifically, the signal processing unit 25 converts the detection signal from the detector 7 into a contrast of a gray level (the gray level), and monitors this contrast information. As shown in FIG. 5, the gray level from a portion in which the contact hole patterns CPs are formed noticeably changes the contrast to form a peak, and hence the peak position may be recognized as a Y-coordinate position Y1 of the center of the pattern. When the signal processing unit 25 detects the peak position of the contrast, the unit recognizes this position as the Y-coordinate position Y1 of the center line ML of the inspection region RB, and sends the position as the positional information to the scanning procedure determination unit 41.

The scanning procedure determination unit 41 determines procedures of the scanning lines 2 to 4 to acquire the SEM images of the contact hole patterns CPs on the basis of the positional information sent from the signal processing unit 25, and gives the procedures to the deflector control unit 24.

The deflector control unit 24 generates the deflection control signal in accordance with the scanning procedure sent from the scanning procedure determination unit 41 and sends the signal to the deflector 5. In consequence, the deflector 5 scans, with the beam, the inspection region RB having the width of ΔY which is specified by the recipe, based on the detected Y-coordinate (Y1) (the scanning lines 2 to 4), and the SEM image of each contact hole pattern CP is acquired by the detector 7, the signal processing unit 25 and the image generation unit 31.

When the scanning of the inspection region RB with the beam (the scanning lines 2 to 4) ends, the electron gun 6 generates the electron beam 1 upon receiving the control signal from the electron gun control unit 22. Furthermore, upon receiving the control signal from the deflector control unit 24, the deflector 5 shifts a beam scanning position as much as a distance of the second pitch PT2 from the nearest beam scanning position (e.g., a beam inspection start position in the inspection region RB1) in the Y-direction to perform the electron beam scanning for the position detection again (a scanning line 5 of FIG. 4). In consequence, a position Y2 of the inspection region RB2 next to the inspection region RB1 in the Y-direction is detected.

Furthermore, similarly to the abovementioned scanning lines 2 to 4, the deflector 5 performs the beam scanning for the inspection (scanning lines 6 to 8) over the inspection region RB2 specified by the recipe, based on the detected Y-coordinate (Y2), and the SEM image of each contact hole pattern CP in the inspection region RB2 is acquired by the detector 7, the signal processing unit 25 and the image generation unit 31.

Afterward, the abovementioned series of operations are repeated until the last inspection region RB is reached, so that it is possible to securely acquire the SEM images from all the inspection regions RBs. The obtained SEM images are successively inspected by the inspection unit 33, and the presence of the defect of the contact hole pattern CP, the type of defect, the degree of the defect and the like are detected by the die to die inspection or the die to database inspection.

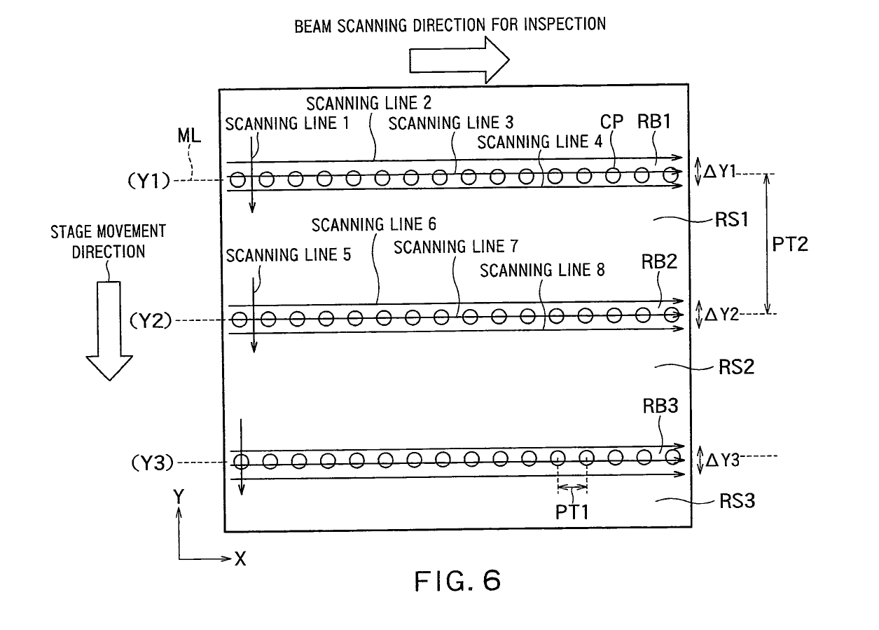

When the pattern pitch PT1 in an electron beam scanning direction for the inspection is comparatively large, as shown in FIG. 6, there is considered a case where the contact hole pattern CP cannot be scanned in the beam scanning for the position detection (the scanning line 1, 5), and the peak of the contrast of the gray level cannot be detected. In this case, the position of the inspection region RB in the Y-direction cannot be specified.

In such a case, when the scanning for the inspection is performed so that the electron beam forms an angle other than 90° to the electron beam scanning direction for the inspection, it is possible to improve a detection success ratio of the contrast peak.

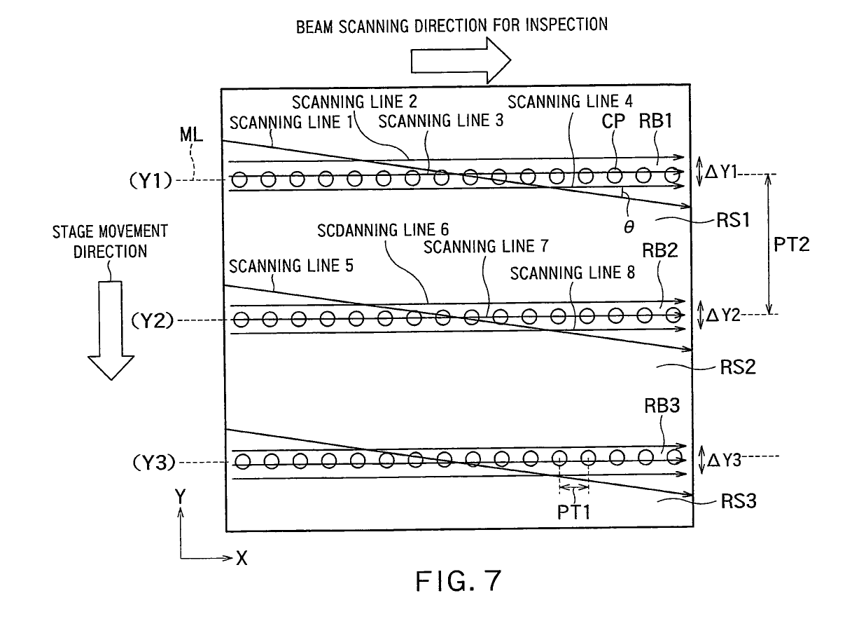

When the scanning procedure determination unit 41 fails in detection of the contrast peak, as shown in FIG. 7, a direction forming an angle θ (≠90) to the electron beam scanning direction (the X-direction) for the inspection may be set to the beam scanning direction for the position detection, in addition to the beam scanning procedure for the inspection. Furthermore, the deflector 5 may be controlled via the deflector control unit 24 so that the electron beam 1 is deflected in this direction.

The angle θ is preferably set to such a value as to satisfy:

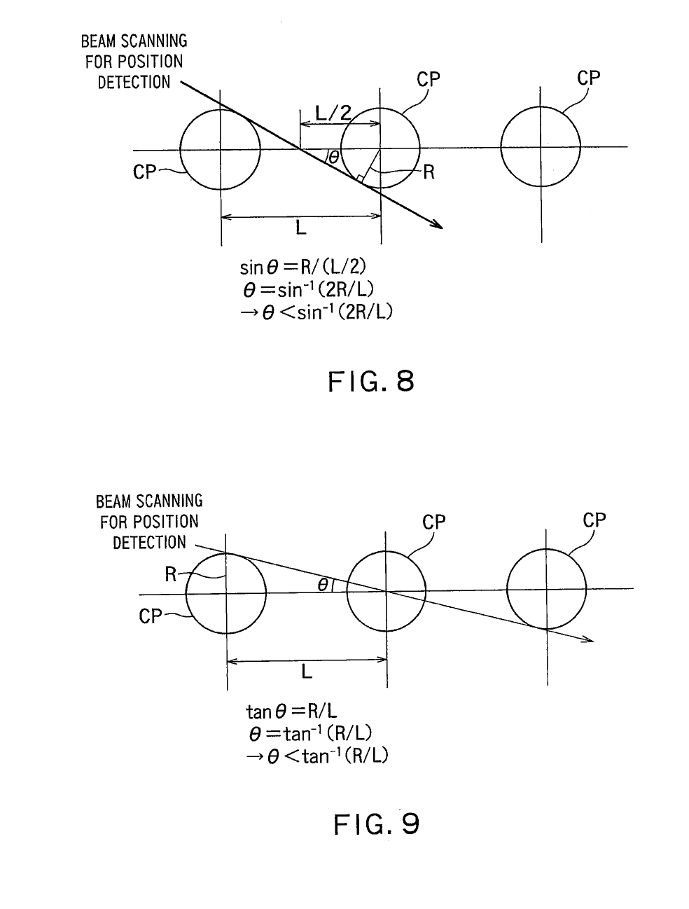

θ<sin⁻¹(2R/L) Formula (1),

in which R is a radius of a hole on design of each contact hole pattern CP, and L is the pattern pitch PT1. In consequence, as shown in FIG. 8, the contact hole patterns CPs are securely scanned, and it is possible to securely detect the position of the inspection region RB in the Y-direction.

Furthermore, when the angle θ is set to such a value as to satisfy:

θ<tan⁻¹(R/L) Formula (2),

it is possible to securely scan across two or more contact hole patterns CPs as shown in FIG. 9. In consequence, it is possible to further improve a detection accuracy of the position of the inspection region RB in the Y-direction.

In a method of specifying the position of the inspection region RB in the Y-direction from a distribution of the gray level, a position which divides a whole volume value of the gray level into two equal portions may be specified as the position of the inspection region RB in the Y-direction even in any beam scanning direction for the position detection, i.e., at any angle θ.

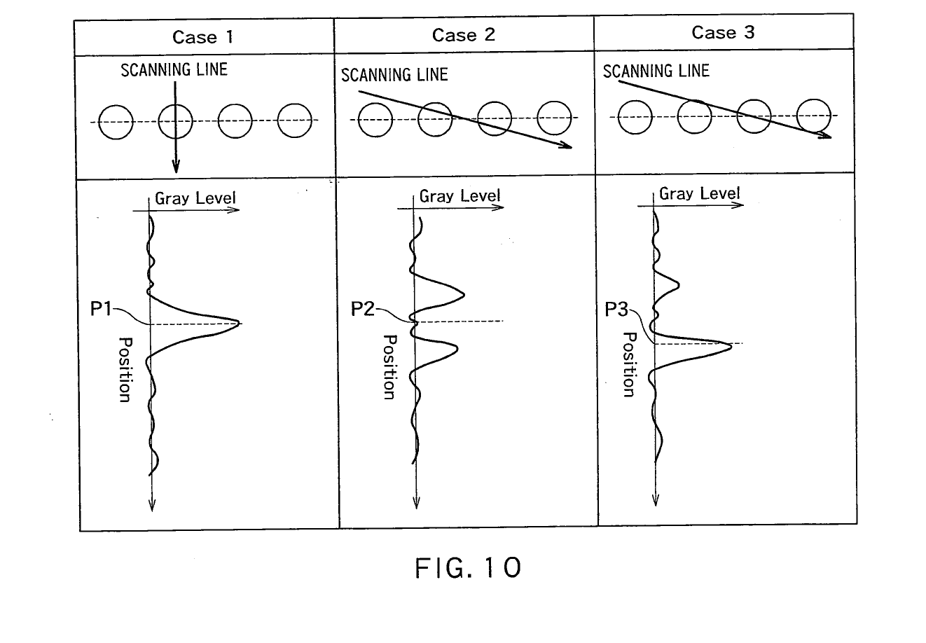

FIG. 10 shows a relation between each of the abovementioned three angles θ and the gray level distribution at the angle. In Case 1, the angle θ is set to satisfy θ=90°, and a position P1 corresponding to the peak of the contrast is the position of the inspection region RB in the Y-direction. In Case 2 and Case 3, the angles θ are set to satisfy θ<tan⁻¹(R/L), and positions P2, P3, each of which divides the whole volume value of the corresponding gray level into two equal portions, are the positions of the inspection regions RBs in the Y-direction, respectively.

In the above description, the beam scanning for the position detection is performed every pair of the inspection region RB and the non-inspection region RS. However, it is also considered that the smaller the pattern pitch PT1 is, the more the number of times of the beam scanning for the detection of the position of the inspection region RB increases. As a result, the inspection time disadvantageously rather lengthens. In this case, the beam scanning for the position detection is not performed every pair of the regions, but may be performed once over a plurality of pairs of the inspection regions RB and the non-inspection regions RS, and the beam scanning position may periodically be corrected on the basis of the obtained positional information.

There is not any special restriction on the number of the pairs of the inspection regions RB and the non-inspection regions RS, but the number is preferably the number of such a degree that there is not an influence such as a change of the beam scanning position due to generation of a wafer charge as a result of the repeated electron beam scanning.

At least one charged particle beam apparatus described above includes the signal processing unit 25 which outputs the positional information of the inspection region RB in the Y-direction by the beam scanning for the position detection prior to the acquisition of the image, and the scanning procedure determination unit 41 which determines the beam scanning procedure for the inspection on the basis of the obtained positional information in the Y-direction, so that it is possible to stably and correctly scan the desirable inspection object pattern with the beam while successively monitoring the position of the inspection object pattern. In consequence, there is provided the charged particle beam apparatus having less pseudo defects and a high inspection accuracy.

(2) Charged Particle Beam Scanning Method

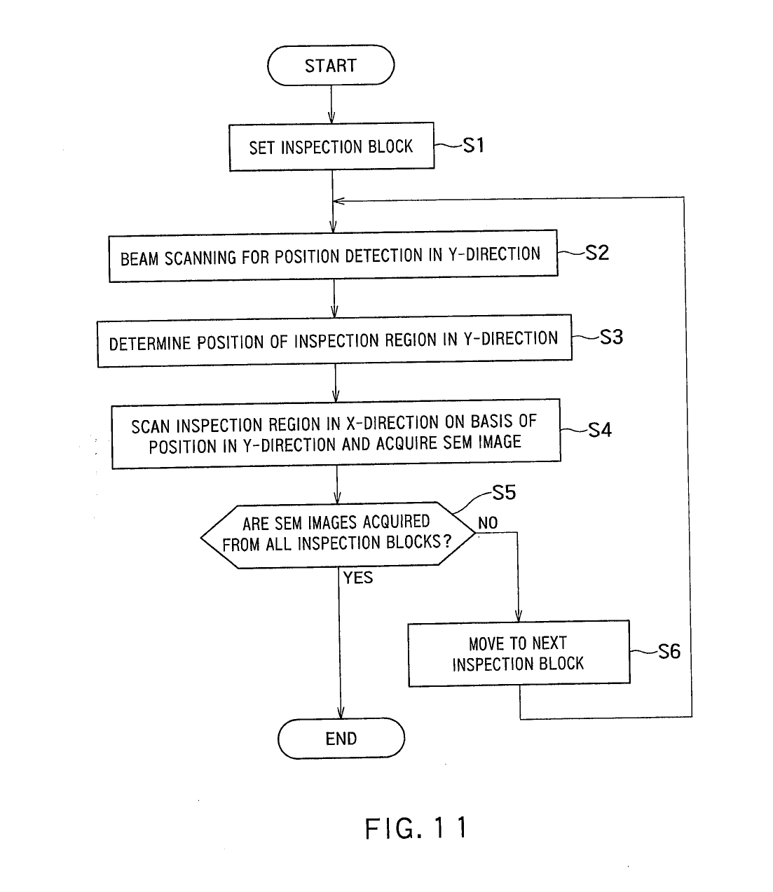

For a charged particle beam scanning method according to one embodiment, an embodiment applied to the acquisition of the SEM image of the inspection object pattern will be described with reference to a flowchart of FIG. 11.

First, there is set an inspection block including a pair or a plurality of pairs of the inspection regions RB where the inspection object patterns are arranged to form each row and the non-inspection regions RS (see FIG. 4) adjacent to the inspection regions RB (step S1). This inspection block corresponds to, for example, an inspection unit in the present embodiment.

Next, the beam scanning for the position detection (the scanning line 1) is performed in a direction intersecting the beam scanning direction for the inspection over the inspection region RB, i.e., the Y-direction in the example shown in FIG. 5 (step S2). In consequence, the detection signal of the secondary electrons and the like emitted from the substrate is analyzed to specify the position of the inspection region RB in the Y-direction (step S3). The electron beam of the scanning for the position detection in this manner corresponds to, for example, a first charged particle beam in the present embodiment.

Subsequently, the inspection region RB is scanned with the beam in a direction parallel to the pattern rows on the basis of the specified position of the inspection region in the Y-direction, i.e., the X-direction in the example shown in FIG. 5, and the detection signal of the secondary electrons and the like from the substrate is processed to acquire the SEM image of the inspection object pattern (step S4). When the die to die inspection, the die to database inspection or the like is performed to the obtained SEM image, the presence of the defect of the inspection object pattern, the type of defect or the degree of the defect can be detected. The electron beam of the scanning for the inspection corresponds to, for example, a second charged particle beam in the present embodiment.

The procedure of the above steps S2 to S4 is repeatedly executed until the SEM images are acquired from the inspection regions RBs of all the inspection blocks. When the inspection block which is not scanned with the beam for the inspection remains (step S5, NO), the stage is moved to the next inspection block (step S6), and the scanning for the position detection is performed again. When the SEM images are acquired from the inspection regions RBs of all the inspection blocks (step S5, YES), the electron beam scanning ends.

According to at least one charged particle beam scanning method described above, the position of the inspection region RB in the Y-direction is specified by the beam scanning for the position detection prior to the beam scanning for the inspection, and the electron beam scanning for the inspection is performed on the basis of the specified position of the inspection region in the Y-direction. Therefore, it is possible to stably and correctly scan the desirable inspection object pattern with the beam while successively monitoring the position of the inspection object pattern. In consequence, there is provided the charged particle beam scanning method which enables the inspection having less pseudo defects and a high accuracy.

(3) Program

In the abovementioned embodiment, there has been described the pattern inspection in which the electron beam apparatus shown in FIG. 1 is used, but the abovementioned series of inspections may be incorporated as the recipe file in a program, read and executed by a general purpose computer connectable to an electron microscope. In consequence, the pattern inspection according to the abovementioned embodiment can be realized by using the general purpose computer.

Furthermore, the abovementioned series of pattern inspection procedures may be incorporated in a program to be executed by the computer, stored in a recording medium such as a flexible disk or a CD-ROM, and read and executed by the computer. The recording medium is not limited to a portable medium such as a magnetic disk or an optical disk, and may be a fixed type recording medium such as a hard disk drive or a memory. Furthermore, the abovementioned program in which the series of pattern inspection procedures are incorporated may be distributed via a communication line such as an internet (including radio communication). Furthermore, the abovementioned program in which the series of pattern inspection procedures are incorporated may be distributed via a wire circuit such as the internet or a radio link, or stored in the recording medium and distributed, in an encrypted, modulated or compressed state.

(4) Manufacturing Method of Semiconductor Device

A semiconductor device is manufactured by a process including a highly accurate inspection step in which the abovementioned pattern inspection is used, so that it is possible to manufacture the semiconductor device with high throughput and yield.

More specifically, a substrate is sampled by the unit of a manufacturing lot, and patterns formed in the sampled substrate are inspected by the abovementioned pattern inspection method. As a result of the inspection, when it is judged that the substrate is a non-defective product, the remaining manufacturing process is continuously executed for the whole manufacturing lot to which the inspected substrate belongs. On the other hand, as the result of the inspection, when it is judged that the substrate is a defective product and rework processing is possible, the rework processing is executed for the manufacturing lot to which the substrate judged as the defective product belongs. When the rework processing ends, the substrate is sampled from the manufacturing lot and inspected again. When it is judged by the re-inspection that the sampled substrate is the non-defective product, the remaining manufacturing process is executed for the manufacturing lot in which the rework processing has ended. Furthermore, when the rework processing is impossible, the manufacturing lot to which the substrate judged as the defective product belongs is discarded, and a defect generating cause is analyzed to feed the cause back to a person in charge of design, a person in charge of an upstream process or the like.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A charged particle beam apparatus comprising:
a charged particle source configured to generate a charged particle beam and to irradiate a substrate with the charged particle beam, the substrate comprising an inspection region and a non-inspection region, a plurality of inspection object patterns being arranged in the inspection region;
a detection unit configured to detect secondary charged particles from the substrate irradiated with the charged particles and to output a signal;
a deflector configured to scan the substrate with the charged particle beam;
a signal processing unit configured to process the signal outputted from the detection unit by scanning with a first beam for position detection and to output positional information of the inspection region in a first direction;
a scanning procedure determination unit configured to determine a procedure of scanning with a second beam for inspection on the basis of the positional information;
a deflector control unit configured to control the deflector in such a manner that the inspection region is scanned with the second beam in a second direction intersecting the first direction in accordance with the determined scanning procedure; and
a control unit configured to control the charged particle source and the deflector control unit in such a manner that the scanning with the first and the second beams is performed for every inspection unit constituted of a pair or a plurality of pairs of the inspection regions and the non-inspection regions.

2. The apparatus of claim 1,
wherein the first direction intersects the second direction with an angle θ (0<θ<90°) in a plane parallel to a principal surface of the substrate.

3. The apparatus of claim 1,
wherein the inspection object patterns are a plurality of hole patterns periodically arranged in the second direction, and
an angle θ of the first direction to the second direction in a plane parallel to a principal surface of the substrate is:
θ<sin⁻¹(2R/L) Formula (1),
in which L is a periodic pitch of the hole patterns, and R is a radius of each hole pattern.

4. The apparatus of claim 1,
wherein the inspection object patterns are a plurality of hole patterns periodically arranged in the second direction, and
an angle θ of the first direction to the second direction in a plane parallel to a principal surface of the substrate is:
θ<tan⁻¹(R/L) Formula (2),
in which L is a periodic pitch of the hole patterns, and R is a radius of each hole pattern.

5. The apparatus of claim 1,
wherein the first direction is perpendicular to the second direction.

6. The apparatus of claim 1,
wherein the inspection object patterns are arranged to form row patterns at a first pitch in the second direction in the inspection region, and
the inspection regions are arranged at a second pitch larger than the first pitch in the first direction in such a manner that the non-inspection region is sandwiched between the inspection regions.

7. The apparatus of claim 1, further comprising:
an image generation unit configured to process the signal outputted from the detection unit by the scanning with the second beam and to generate an image of each of the patterns; and
an inspection unit configured to inspect the pattern based on the image.

8. A charged particle beam scanning method comprising:
scanning a substrate with a first charged particle beam in a first direction, to analyze secondary charged particles obtained from the substrate comprising an inspection region where a plurality of inspection object patterns are arranged and a non-inspection region, thereby specifying a position of the inspection region in the first direction; and
scanning the substrate with a second charged particle beam in a second direction intersecting the first direction on the basis of the specified position,
wherein the scanning with the first and second charged particle beams is performed for every inspection unit constituted of a pair or a plurality of pairs of the inspection regions and the non-inspection regions.

9. The method of claim 8,
wherein the first direction intersects the second direction with an angle θ (0<θ<90°) in a plane parallel to a principal surface of the substrate.

10. The method of claim 8,
wherein the inspection object patterns are a plurality of hole patterns periodically arranged in the second direction, and
an angle θ of the first direction to the second direction in a plane parallel to a principal surface of the substrate is:
θ<sin⁻¹(2R/L) Formula (1),
in which L is a periodic pitch of the hole patterns, and R is a radius of each hole pattern.

11. The method of claim 8,
wherein the inspection object patterns are a plurality of hole patterns periodically arranged in the second direction, and
an angle θ of the first direction to the second direction in a plane parallel to a principal surface of the substrate is:
θ<tan⁻¹(R/L) Formula (2),
in which L is a periodic pitch of the hole patterns, and R is a radius of each hole pattern.

12. The method of claim 8,
wherein the first direction is perpendicular to the second direction.

13. The method of claim 8,
wherein the inspection object patterns are arranged to form row patterns at a first pitch in the second direction in the inspection region, and
the inspection regions are arranged at a second pitch larger than the first pitch in the first direction in such a manner that the non-inspection region is sandwiched between the inspection regions.

14. A non-transitory computer-readable recording medium storing a program allowing a computer to execute a pattern inspection, the computer being connected to a charged particle beam apparatus configured to generate a charged particle beam, to irradiate a substrate comprising patterns with the charged particle beam, to detect secondary charged particles from the substrate and to acquire charged particle images of the patterns, the inspection comprising:
scanning the substrate with a first charged particle beam in a first direction, to analyze secondary charged particles obtained from the substrate comprising an inspection region where a plurality of inspection object patterns are arranged and a non-inspection region, thereby specifying a position of the inspection region in the first direction;
scanning the substrate with a second charged particle beam in a second direction intersecting the first direction on the basis of the specified position;
detecting the secondary charged particles from the substrate by scanning the substrate in the second direction to generate an image of each of the patterns; and
inspecting the pattern from the image,
wherein the scanning with the first and second charged particle beams is performed for every inspection unit constituted of a pair or a plurality of pairs of the inspection regions and the non-inspection regions.

15. The medium of claim 14,
wherein the first direction intersects the second direction with an angle θ (0<θ<90°) in a plane parallel to a principal surface of the substrate.

16. The medium of claim 14,
wherein the inspection object patterns are a plurality of hole patterns periodically arranged in the second direction, and
an angle θ of the first direction to the second direction in a plane parallel to a principal surface of the substrate is:
θ<sin⁻¹(2R/L) Formula (1),
in which L is a periodic pitch of the hole patterns, and R is a radius of each hole pattern.

17. The medium of claim 14,
wherein the inspection object patterns are a plurality of hole patterns periodically arranged in the second direction, and
an angle θ of the first direction to the second direction in a plane parallel to a principal surface of the substrate is:
θ<tan⁻¹(R/L) Formula (2),
in which L is a periodic pitch of the hole patterns, and R is a radius of each hole pattern.

18. The medium of claim 14,
wherein the first direction is perpendicular to the second direction.
